(19) United States
(12) Patent Application Publication
(10) Pub. No.: US 2023/0243968 A1
(43) Pub. Date: Aug. 3, 2023

(54) DISTANCE MEASUREMENT APPARATUS AND NON-TRANSITORY COMPUTER READABLE MEDIUM STORING DISTANCE MEASUREMENT PROGRAM

(71) Applicant: FUJIFILM Business Innovation Corp., Tokyo (JP)

(72) Inventors: Junichiro HAYAKAWA, Kanagawa (JP); Tomoaki SAKITA, Kanagawa (JP); Kei TAKEYAMA, Kanagawa (JP); Daisuke IGUCHI, Kanagawa (JP); Takashi KONDO, Kanagawa (JP); Yoshihiro YAMAMOTO, Kanagawa (JP)

(73) Assignee: FUJIFILM Business Innovation Corp., Tokyo (JP)

(21) Appl. No.: 17/889,340

(22) Filed: Aug. 16, 2022

(30) Foreign Application Priority Data
Feb. 2, 2022 (JP) 2022-015121

(51) Int. Cl. G01S 17/08; G01S 7/481

(52) U.S. Cl. CPC G01S 17/08; G01S 7/481

(57) ABSTRACT

A distance measurement apparatus includes a light emitting unit that has plural light emitting elements, and is able to be driven independently in plural regions, a light receiving unit provided with plural light receiving elements that receive reflected light of light applied to an object from the light emitting unit, a shaping unit that causes an overlapping portion to be generated in which light reception of the reflected light overlaps in the adjacent regions, on the light receiving unit, a measurement unit that measures a distance to the object, from a difference between a waveform of light received by the light receiving unit and a waveform of light emitted by the light emitting unit, and a correction unit that corrects a distance difference in the reflected light in the adjacent regions, by using a distance measurement value in the overlapping portion measured by the measurement unit.

### CROSS-REFERENCE TO RELATED APPLICATIONS

This application is based on and claims priority under 35 USC 119 from Japanese Patent Application No. 2022-015121 filed Feb. 2, 2022.

### BACKGROUND

### (i) Technical Field

The present invention relates to a distance measurement apparatus and a non-transitory computer readable medium storing a distance measurement program.

### (ii) Related Art

JP2020-148682A proposes a distance measurement apparatus including: a light receiving unit having a plurality of pixels; a reference time measurement unit that is connected to a reference signal line connected to a specific pixel among the plurality of pixels, and measures a reference time value from a first light emission timing by first light emission control on a light emitting unit to a light receiving timing in the specific pixel; a time measurement unit that is connected to a signal main line connected to the specific pixel, and measures a predetermined time value from the first light emission timing to the light receiving timing; and a correction processing unit that calculates and stores a correction value for the signal main line, based on the reference time value and the predetermined time value, in which the slow speed of the signal output from the specific pixel via the signal main line in response to second light emission control for the light emitting unit is corrected based on the stored correction value.

Specifically, even in a case where light at the same light emission timing is reflected by an object to be measured at the same distance and received, there is a difference in the distance calculated for each pixel of the sensor array due to the physical difference in the signal line connected to each pixel. Therefore, in order to correct the difference between the pixels, with the output value of one pixel as a reference, it is proposed to correct the output signal from the sensor such that the output values of the other pixels are adjusted to the reference.

### SUMMARY

In a light emitting unit provided with a plurality of light emitting elements, a deviation is generated in the light emission timing of each light emitting element due to external factors such as driving conditions and temperature conditions, individual differences, and changes overtime. Ina case where such a deviation in the light emission timing occurs in the light emitting unit, in a case where the light emitting elements are independently driven in a plurality of regions to measure the distance to the object, there is a distance difference due to the deviation in the light emission timing in the regions.

Aspects of non-limiting embodiments of the present disclosure relate to a distance measurement apparatus and a non-transitory computer readable medium storing a distance measurement program capable of correct a distance difference that occurs between the regions in a case where a distance to the object is measured by independently driving light emitting elements in a plurality of regions.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided a distance measurement apparatus including: a light emitting unit that has a plurality of light emitting elements, and is able to be driven independently in a plurality of regions; a light receiving unit provided with a plurality of light receiving elements that receive reflected light of light applied to an object from the light emitting unit; a shaping unit that causes an overlapping portion to be generated in which light reception of the reflected light overlaps in the adjacent regions, on the light receiving unit; a measurement unit that measures a distance to the object, from a difference between a waveform of light received by the light receiving unit and a waveform of light emitted by the light emitting unit; and a correction unit that corrects a distance difference in the reflected light in the adjacent regions, by using a distance measurement value in the overlapping portion measured by the measurement unit.

### BRIEF DESCRIPTION OF THE DRAWINGS

Exemplary embodiment(s) of the present invention will be described in detail based on the following figures, wherein:

FIG. 1 is a schematic configuration diagram showing a configuration of a measurement apparatus according to a first exemplary embodiment;

FIG. 2 is a block diagram showing a configuration of a main part of an electrical system of the measurement apparatus;

FIG. 3 is a plan view of a light source;

FIG. 4 is a diagram for explaining a light emitting section;

FIG. 5 is a circuit diagram of the measurement apparatus;

FIG. 6 is a plan view of a 3D sensor;

FIG. 7A is a diagram showing an optical device according to the first exemplary embodiment, and FIG. 7B is a diagram showing a light emitting unit, a focal length of a lens, and a position of the light emitting unit;

FIG. 8 is a diagram showing conditions for generating an overlapping portion;

FIG. 9 is a flowchart showing the flow of a calibration process executed by a control unit of the measurement apparatus according to the first exemplary embodiment;

FIG. 10 is a diagram showing an example of a reference and a measurement order of the light emitting section;

FIG. 11 is a diagram showing an optical device according to a second exemplary embodiment;

FIG. 12 is a diagram showing an example in which an overlapping portion is generated so as to overlap VCSELs of a part of adjacent light emitting sections in the optical device according to the third exemplary embodiment (light emitted from VCSELs near the gate electrode is overlapped);

FIG. 13 is a diagram showing an example in which an overlapping portion is generated so as to overlap VCSELs of apart of adjacent light emitting sections in the optical device according to the third exemplary embodiment (light emitted from VCSELs far from the gate electrode is overlapped);

FIG. 14 is a diagram showing an example in which light emitted from VCSELs of adjacent portions at corners in the respective light emitting sections is overlapped, in the optical device according to the third exemplary embodiment; and

FIG. 15 is a diagram for explaining an optical device according to a fourth exemplary embodiment.

### DETAILED DESCRIPTION

Hereinafter, exemplary embodiments of the present invention will be described in detail with reference to the drawings.

### First Exemplary Embodiment

As a measurement apparatus for measuring the three-dimensional shape of an object to be measured, there is an apparatus that measures the three-dimensional shape based on the so-called time of flight (ToF) method using the time of flight of light. In the ToF method, the three-dimensional shape is specified by measuring the time from the timing when the light is emitted from the light source of the measurement apparatus to the timing when the emitted light is reflected by the object to be measured and is received by the three-dimensional sensor (hereinafter referred to as a 3D sensor) of the measurement apparatus, and measuring the distance to the object to be measured. The object for which the three-dimensional shape is to be measured is referred to as an object to be measured. The object to be measured corresponds to an example of the object. Further, measuring a three-dimensional shape may be referred to as three-dimensional measurement, 3D measurement, or 3D sensing.

The ToF method includes a direct method and a phase difference method (indirect method). In the direct method, the object to be measured is irradiated with pulsed light that emits light for a very short time, and the time until the light returns is actually measured. In the phase difference method, the pulsed light blinks periodically, and the time delay when a plurality of pulsed light beams reciprocate to the object to be measured is detected as a phase difference. In the present exemplary embodiment, a case where a three-dimensional shape is measured by the phase difference method will be described.

Such a measurement apparatus is mounted on a portable information processing apparatus or the like, and is used for face recognition of a user who intends to access. In the related art, in the portable information processing apparatuses, or the like, a method of authenticating a user by a password, a fingerprint, an iris, or the like has been used. In recent years, more secure authentication methods have been required. Therefore, a measurement apparatus that measures a three-dimensional shape is mounted on a portable information processing apparatus. In other words, a three-dimensional image of the face of the user who has accessed is acquired, whether or not the access is permitted is identified, and only in a case where it is authenticated that the user is authorized to access, the user is permitted to use a host apparatus (portable information processing apparatus).

Further, such a measurement apparatus is also applied to the case of continuously measuring the three-dimensional shape of the object to be measured, such as augmented reality (AR).

The configurations, functions, methods, and the like described in the present exemplary embodiment described below can be applied not only to face recognition and augmented reality, but also to the measurement of the three-dimensional shape of other objects to be measured.

Measurement Apparatus 1

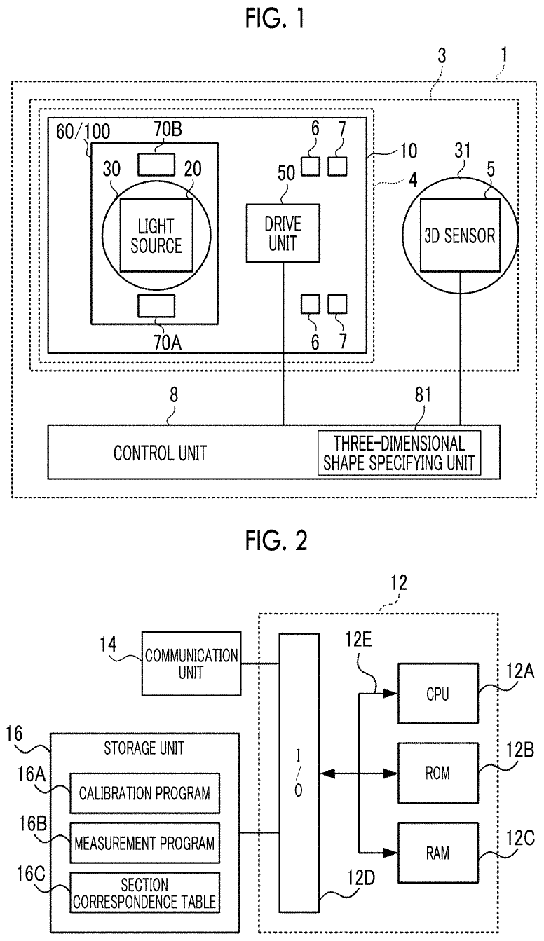

FIG. 1 is a block diagram showing an example of the configuration of a measurement apparatus 1 that measures a three-dimensional shape.

The measurement apparatus 1 includes an optical device 3 and a control unit 8. The control unit 8 controls the optical device 3. The control unit 8 includes a three-dimensional shape specifying unit 81 that specifies the three-dimensional shape of the object to be measured. The measurement apparatus 1 is an example of a distance measurement apparatus. Further, the control unit 8 is an example of a measurement unit and a correction unit.

FIG. 2 is a block diagram showing a hardware configuration of the control unit 8. As shown in FIG. 2, the control unit 8 includes a controller 12. The controller 12 includes a central processing unit (CPU) 12A, a read only memory (ROM) 12B, a random access memory (RAM) 12C, and an input/output interface (I/O) 12D. The CPU 12A, the ROM 12B, the RAM 12C, and the I/O 12D are each connected via a system bus 12E. The system bus 12E includes a control bus, an address bus, and a data bus.

Further, a communication unit 14 and a storage unit 16 are connected to the I/O 12D.

The communication unit 14 is an interface for performing data communication with an external device.

The storage unit 16 is composed of a non-volatile rewritable memory such as a flash ROM, and stores a calibration program 16A to be described later, a measurement program 16B, a section correspondence table 16C to be described later, or the like. The CPU 12A calibrates the optical device 3 by reading the calibration program 16A stored in the storage unit 16 into the RAM 12C and executing the calibration program 16A. Further, reading the measurement program 16B stored in the storage unit 16 into the RAM 12C and executing the measurement program 16B configure the three-dimensional shape specifying unit 81, and the three-dimensional shape of the object to be measured is specified. The calibration program 16A is an example of a distance measurement program.

The optical device 3 includes a light emitting device 4 and a 3D sensor 5. The light emitting device 4 includes a wiring board 10, a heat dissipation base material 100, a light source 20, a drive unit 50, a holding unit 60, and capacitors 70A and 70B. Further, the light emitting device 4 may include a passive element such as a resistance element 6 and a capacitor 7 in order to operate the drive unit 50. Here, it is assumed that two resistance elements 6 and two capacitors 7 are provided. Further, although the two capacitors 70A and 70B are described, one may be used. When the capacitors 70A and 70B are not distinguished, the capacitors 70A and 70B are referred to as capacitors 70. Further, the numbers of the resistance elements 6 and the capacitors 7 may be one or plural, respectively. Here, electric components such as the 3D sensor 5, the resistance element 6, and the capacitor 7 other than the light source 20, the drive unit 50, and the capacitor 70 may be referred to as circuit components without distinction. The light source 20 is an example of a light emitting unit, and the 3D sensor 5 is an example of a light receiving unit.

The heat dissipation base material 100, the drive unit 50, the resistance element 6 and the capacitor 7 of the light emitting device 4 are provided on the surface of the wiring board 10. Although the 3D sensor 5 is not provided on the surface of the wiring board 10 in FIG. 1, the 3D sensor 5 may be provided on the surface of the wiring board 10.

The light source 20, the capacitors 70A and 70B, and the holding unit 60 are provided on the surface of the heat dissipation base material 100. Here, the surface means the front side of the paper surface of FIG. 1. More specifically, in the wiring board 10, the side on which the heat dissipation base material 100 is provided is referred to as a surface, a front side, or a surface side. Further, in the heat dissipation base material 100, the side provided with the light source 20 is referred to as a surface, a front side, or a surface side.

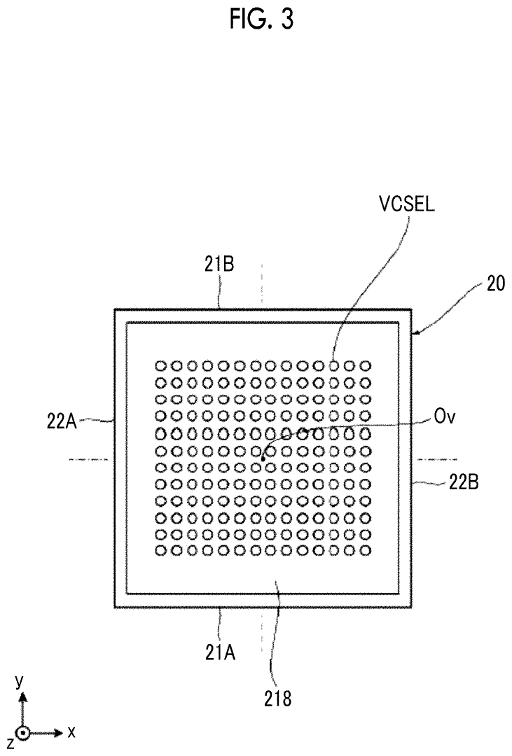

The light source 20 is configured as a light emitting element array in which a plurality of light emitting elements are disposed two-dimensionally (see FIG. 3 described later). The light emitting element is, for example, vertical cavity surface emitting laser VCSEL. Hereinafter, the light emitting element will be described as a vertical cavity surface emitting laser VCSEL. Since the light source 20 is provided on the surface of the heat dissipation base material 100, the light source 20 emits light perpendicular to the surface of the heat dissipation base material 100 and in a direction away from the heat dissipation base material 100. That is, the light emitting element array is a surface emitting laser array. It should be noted that a plurality of light emitting elements in the light source 20 are disposed two-dimensionally, and the surface of the light source 20 that emits light may be referred to as an emission surface.

An irradiation optical system 30 as an example of the shaping unit is provided on the light emitting side of the light source 20, and the light emitted from the light source 20 irradiates the object to be measured via the irradiation optical system 30. The irradiation optical system 30 is configured with, for example, one or more lenses. The irradiation optical system 30 may diffuse and emit light.

In a case where three-dimensional measurement is performed by the ToF method, the light source 20 is required to emit pulsed light (hereinafter, referred to as an emitted light pulse) of, for example, 100 MHz or more and a rise time of 1 ns or less by the drive unit 50. In the case of face recognition as an example, a distance from which light emits is about 10 cm to 1 m. The range to which light is applied is about 1 m square. The distance from which light emits is referred to as a measurement distance, and the range to which light is applied is referred to as an irradiation range or a measurement range. Further, a surface virtually provided in the irradiation range or the measurement range is referred to as an irradiation surface. In addition, the measurement distance to the object to be measured and the irradiation range for the object to be measured may be other than the above, such as in cases other than face recognition.

The 3D sensor 5 includes a plurality of light receiving elements, for example, 640×480 light receiving elements, and outputs a signal corresponding to the time from the timing when light is emitted from the light source 20 to the timing when light is received by the 3D sensor 5. Further, the 3D sensor 5 includes a condensing optical system 31, and light is input through the condensing optical system 31.

For example, each light receiving element of the 3D sensor 5 receives the pulse-shaped reflected light (hereinafter referred to as a received light pulse) from the object to be measured with respect to the emitted light pulse from the light source 20, and accumulates charges corresponding to the time until the light is received, for each light receiving element. The 3D sensor 5 is configured as a device having a CMOS structure in which each light receiving element has two gates and charge storage units corresponding to the gates. Then, by alternately applying pulses to the two gates, the generated photoelectrons are transferred to either of the two charge storage units at high speed. Charges corresponding to the phase difference between the emitted light pulse and the received light pulse are accumulated in the two charge storage units. Then, the 3D sensor 5 outputs a digital value corresponding to the phase difference between the emitted light pulse and the received light pulse as a signal for each light receiving element via the AD converter. That is, the 3D sensor 5 outputs a signal corresponding to the time from the timing when light is emitted from the light source 20 to the timing when light is received by the 3D sensor 5. That is, a signal corresponding to the three-dimensional shape of the object to be measured is acquired from the 3D sensor 5. The AD converter may be provided in the 3D sensor 5 or may be provided outside the 3D sensor 5.

As described above, the measurement apparatus 1 diffuses the light emitted by the light source 20 to irradiate the object to be measured, and receives the reflected light from the object to be measured by the 3D sensor 5. In this way, the measurement apparatus 1 measures the three-dimensional shape of the object to be measured.

First, the light source 20, the irradiation optical system 30, the drive unit 50, and the capacitors 70A and 70B configuring the light emitting device 4 will be described.

Configuration Of Light Source 20

FIG. 3 is a plan view of the light source 20. The light source 20 is configured by arranging a plurality of VCSELs in a two-dimensional array. That is, the light source 20 is configured as a light emitting element array having a VCSEL as a light emitting element. The right direction of the paper surface is defined as an x direction, and the upper direction of the paper surface is defined as a y direction.

The direction orthogonal to the x-direction and the y-direction is defined as a z-direction. The surface of the light source 20 refers to the front side of the paper surface, that is, the surface on the +z direction side, and the back surface of the light source 20 refers to the back side of the paper surface, that is, the surface on the −z direction side. The plan view of the light source 20 is a view of the light source 20 as viewed from the surface side.

More specifically, in the light source 20, the side on which the epitaxial layer that functions as a light emitting layer (active region described later) is formed is referred to as the surface, front side, or surface side of the light source 20.

The VCSEL is a light emitting element in which an active region which is a light emitting region is provided between a lower multilayer film reflecting mirror and an upper multilayer film reflecting mirror stacked on a semiconductor substrate 200 and laser light is emitted in a direction perpendicular to the surface. Therefore, the VCSEL is easier to form a two-dimensional array than the case where the end face emission type laser is used. The number of VCSELs included in the light source 20 is, for example, 100 to 1000. The plurality of VCSELs are connected in parallel to each other and driven in parallel. The above-described number of VCSELs is an example, and may be set according to the measurement distance and the irradiation range.

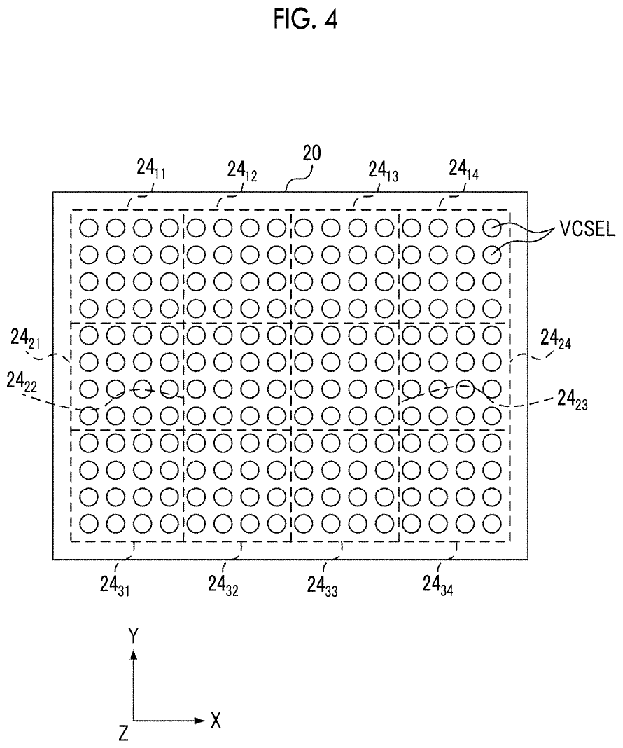

Further, the light source 20 is independently driven in a plurality of regions. For example, as shown in FIG. 4, the light source 20 is divided into a plurality of light emitting sections 24 and is driven for each light emitting section. In the example of FIG. 4, as shown by broken lines, the light source 20 is divided into 12 light emitting sections 24₁₁ to 24₃₄ of 4×3, but the number of light emitting sections is not limited to this. In a case where the light emitting sections are not particularly distinguished, the light emitting section is simply referred to as a light emitting section 24. Further, in the example of FIG. 4, 16 VCSELs are included in one light emitting section 24, but the number of VCSELs included in one light emitting section 24 is not limited to this, and one or more VCSELs may be included.

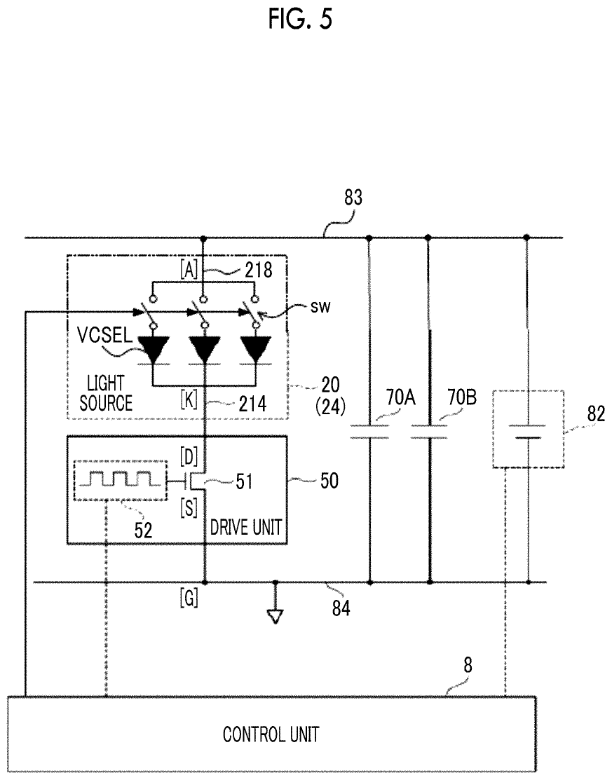

An anode electrode 218 (see FIG. 5) common to a plurality of VCSELs is provided on the surface of the light source 20. A cathode electrode 214 (see FIG. 5) is provided on the back surface of the light source 20. That is, the plurality of VCSELs are connected in parallel. By connecting and driving the plurality of VCSELs in parallel, stronger light is emitted as compared with the case where the VCSELs are individually driven.

Here, in the light source 20, the shape seen from the surface side (referred to as a planar shape. The same shall apply hereinafter.) is a rectangle. The side surface on the −y direction side is referred to as the side surface 21A, the side surface on the +y direction side is referred to as the side surface 21B, the side surface on the −x direction side is referred to as the side surface 22A, and the side surface on the +x direction side is referred to as the side surface 22B. The side surface 21A and the side surface 21B face each other. The side surface 22A and the side surface 22B are connected to the side surface 21A and the side surface 21B, respectively, and face each other.

Then, the center in the planar shape of the light source 20, that is, the center in the x direction and the y direction is defined as the center Ov.

Drive Unit 50 And Capacitors 70A, 70B

In a case where it is desired to drive the light source 20 at a higher speed, the light source 20 is driven may by low-side driving, for example. The low-side driving refers to a configuration in which a drive element such as a MOS transistor is positioned on the downstream side of a current path with respect to a drive target such as a VCSEL. Conversely, a configuration in which the drive element is located on the upstream side is called high-side driving.

FIG. 5 is a diagram showing an example of an equivalent circuit in the case where the light source 20 is driven by low-side driving. FIG. 5 shows the VCSELs of the light source 20, the drive unit 50, the capacitors 70A and 70B, and the power supply 82. The power supply 82 is provided in the control unit 8 shown in FIG. 1. The power supply 82 generates a DC voltage having the +side as the power potential and the-side as the reference potential. The power potential is supplied to a power supply line 83, and the reference potential is supplied to a reference line 84. The reference potential may be a ground potential (may be denoted as (GND). In FIG. 5, denoted as [G].).

As described above, the light source 20 is configured by connecting a plurality of VCSELs in parallel. VCSEL anode electrode 218 (see FIG. 3. In FIG. 5, denoted as [A].) is connected to the power supply line 83.

Further, as described above, the light source 20 is divided into a plurality of light emitting sections 24, and the control unit 8 drives the VCSEL for each light emitting section 24. In FIG. 5, only one light emitting section 24 shows three VCSELs, and the other VCSEL and the light emitting section are not shown.

As shown in FIG. 5, a switch element SW is provided between each VCSEL and the power supply line 83, and each switch element SW is turned on and off at the same time by a command from the control unit 8. Thus, the VCSEL included in one light emitting section 24 is controlled to emit light and not emit light at the same timing.

The drive unit 50 includes an n-channel type MOS transistor 51 and a signal generation circuit 52 that turns the MOS transistor 51 on and off. The drain (denoted as [D] in FIG. 5) of the MOS transistor 51 is connected to the cathode electrode 214 (see FIG. 3. In FIG. 5, denoted as [K].) of the VCSEL. The source (denoted as [S] in FIG. 5) of the MOS transistor 51 is connected to the reference line 84. Then, the gate of the MOS transistor 51 is connected to the signal generation circuit 52. That is, the VCSEL and the MOS transistor 51 of the drive unit 50 are connected in series between the power supply line 83 and the reference line 84. The signal generation circuit 52 generates an “H level” signal for turning on the MOS transistor 51 and an “L level” signal for turning off the MOS transistor 51 under the control of the control unit 8.

One terminal of the capacitors 70A and 70B is connected to the power supply line 83, and the other terminal is connected to the reference line 84. Here, in a case where there are a plurality of capacitors 70, the plurality of capacitors 70 are connected in parallel. That is, in FIG. 5, it is assumed that the capacitors 70 are two capacitors 70A and 70B. The capacitor 70 is, for example, an electrolytic capacitor or a ceramic capacitor.

Next, a method of driving the light source 20, which is the low-side driving, will be described.

First, the control unit 8 turns on the switch element SW of the light emitting section 24 in which the VCSEL is desired to emit light, and turns off the switch element SW in the light emitting section 24 in which the VCSEL is not desired to emit light.

Hereinafter, the driving of the VCSEL included in the light emitting section 24 in which the switch element SW is turned on will be described.

First, it is assumed that the signal generated by the signal generation circuit 52 in the drive unit 50 is “L level”. In this case, the MOS transistor 51 is in the off state. That is, no current flows between the source ([S] in FIG. 5) and the drain ([D] in FIG. 5) of the MOS transistor 51. Therefore, no current flows through the VCSEL connected in series with the MOS transistor 51. That is, the VCSEL does not emit light.

At this time, the capacitors 70A and 70B are connected to the power supply 82, one terminal of the capacitors 70A and 70B connected to the power supply line 83 has the power supply potential, and the other terminal connected to the reference line 84 has a reference potential. Therefore, the capacitors 70A and 70B are charged by a current flowing from the power supply 82 (by charges being supplied).

Next, in a case where the signal generated by the signal generation circuit 52 in the drive unit 50 reaches the “H level”, the MOS transistor 51 shifts from the off state to the on state. Then, a closed loop is formed by the capacitors 70A and 70B, and the MOS transistors 51 and the VCSEL which are connected in series, and the charges accumulated in the capacitors 70A and 70B are supplied to the MOS transistors 51 and the VCSEL which are connected in series. That is, a drive current flows through the VCSEL, and the VCSEL emits light. This closed loop is a drive circuit that drives the light source 20.

Then, in a case where the signal generated by the signal generation circuit 52 in the drive unit 50 reaches the “L level” again, the MOS transistor 51 shifts from the on state to the off state. Thus, the closed loop (drive circuit) between the capacitors 70A and 70B and the MOS transistor 51 and the VCSEL which are connected in series becomes an open loop, and the drive current does not flow through the VCSEL. Thus, the VCSEL stops emitting light. Then, the capacitors 70A and 70B are charged by being supplied with charges from the power supply 82.

As described above, each time the signal output by the signal generation circuit 52 shifts to “H level” and “L level”, the MOS transistor 51 repeatedly turns on and off, and the VCSEL repeatedly emits light and does not emit light. Repeatedly turning on and off the MOS transistor 51 may be referred to as switching.

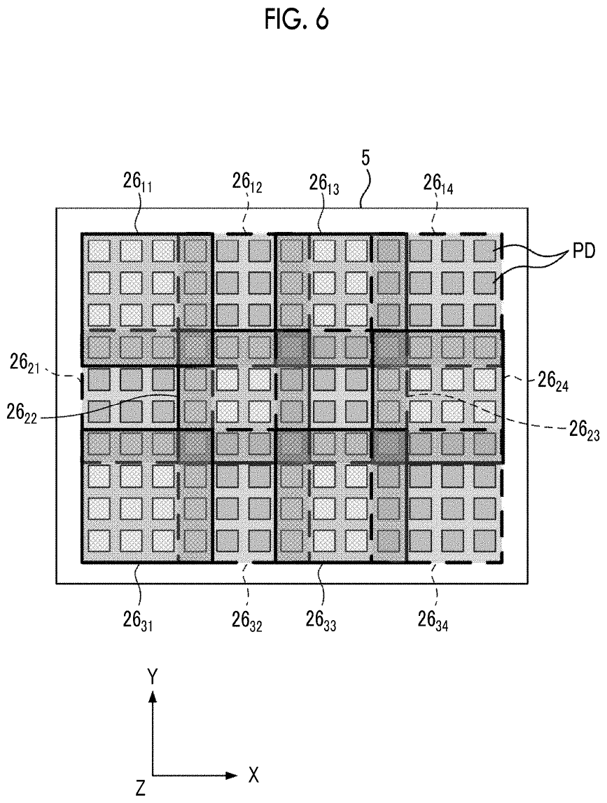

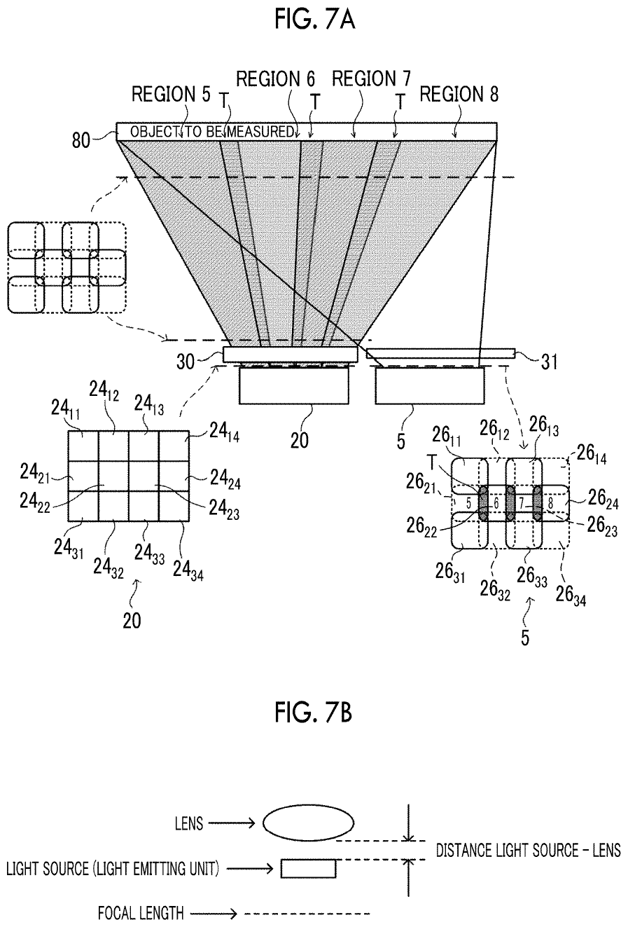

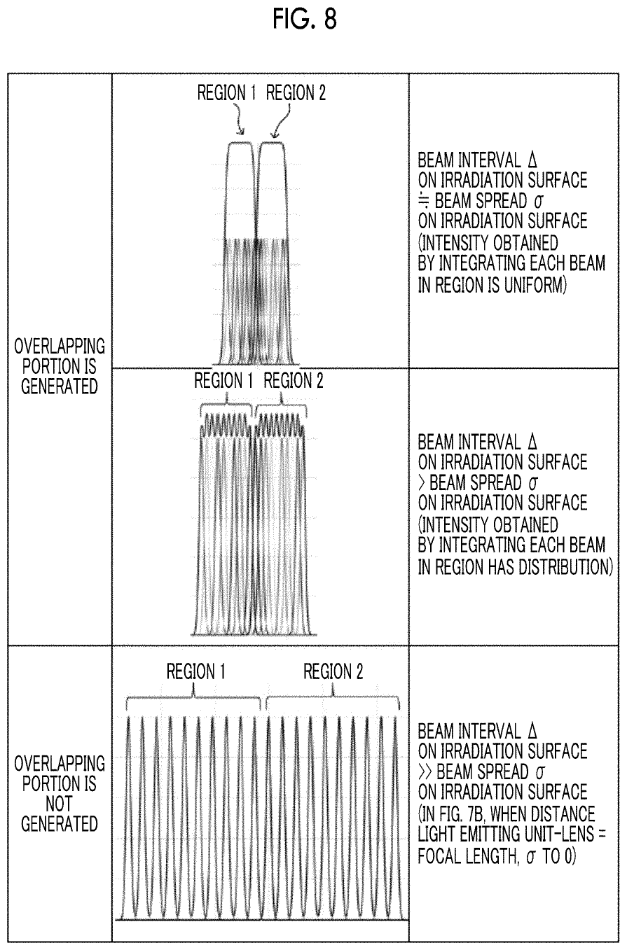

On the other hand, as shown in FIG. 6, the 3D sensor 5 includes a plurality of light receiving elements PD. In the present exemplary embodiment, the 3D sensor 5 is divided into a plurality of light receiving sections 26, and the irradiation optical system 30 shapes the light emitted from each light emitting section 24 which is emitted from the light source 20 such that overlapping portions T (see FIG. 7A) where the adjacent light receiving sections 26 overlap is generated. The light receiving section 26 includes one or more light receiving elements PD. In the example of FIG. 6, one light receiving section 26 includes 16 light receiving elements PD, but the number of light receiving element PDs is not limited to this. In the example of FIG. 6, for convenience of explanation, the 3D sensor 5 is divided into 4×3 light receiving sections 26₁₁ to 26₃₄ as in the light emitting sections 24, but the number of the light receiving sections may be different from the number of the light emitting sections 24. In a case where the light receiving sections are not particularly distinguished, the light receiving section is simply referred to as a light receiving section 26.

Further, in the present exemplary embodiment, it is assumed that the light receiving section 26 to which the light receiving element PD that directly receives the light belongs is specified in advance, for each light emitting section 24, in a case where all the VCSELs belonging to the light emitting section 24 are made to emit light. The correspondence between the light emitting section 24 and the light receiving section 26 is stored in advance in the storage unit 16 as the section correspondence table 16C (see FIG. 2).

The section correspondence table 16C is obtained from, for example, the amount of light received in each light receiving section 26 by individually causing each light emitting section 24 to emit light to a predetermined object to be measured, in the absence of obstacles or the like.

The correspondence between the light emitting sections 24 and the light receiving sections 26 may be any of one-to-one, many-to-one, one-to-many, and many-to-many, but in the present exemplary embodiment, it is assumed that the correspondence is one-to-one for convenience of explanation.

Further, in the present exemplary embodiment, as shown in FIG. 7A, the light emitted from the light source 20 is applied to the object to be measured 80 via the irradiation optical system 30, is reflected by the object to be measured 80, and is input to the 3D sensor 5 via the condensing optical system 31. Here, the irradiation optical system 30 shapes the light from the light source 20 such that an overlapping portion T is generated in which adjacent regions irradiated with light from the plurality of light emitting sections 24 overlap on the object to be measured 80 and the 3D sensor 5. Therefore, the light source 20 is driven for each light emitting section 24, and the adjacent light emitting sections 24 do not overlap. However, light from the light source 20 is shaped and applied to the object to be measured 80 by the irradiation optical system 30 such that the adjacent regions overlap in the regions irradiated from the light emitting sections 24, so that on the object to be measured 80, as shown in FIG. 7A, adjacent regions overlap in the regions corresponding to respective light emitting sections 24 to generates overlapping portions Ts. Then, the light is reflected by the object to be measured 80 and is input to the 3D sensor 5, and an overlapping portion T is generated in the adjacent light receiving sections 26 on the 3D sensor 5. In FIG. 7A, the overlapping portions Ts of the regions 5 to 7 on the 3D sensor 5 are shown by hatching. The overlapping portion T is stored in the storage unit 16 in advance including the correspondence with the light receiving element PD in the section correspondence table 16C.

In FIG. 7B, the irradiation optical system 30 generates the overlapping portion T by, for example, shifting the position of the focal length of the lens from the position of the light emitting unit (light source 20). The lens may be a plurality of lenses, and in the case of a plurality of lenses, the overlapping portion T is generated by shifting the combined focal length of the plurality of lenses from the position of the light emitting unit. In a case of shifting the position of the light emitting unit from the position of the focal length of the lens, the position may be shifted to a side farther from the lens, but for example, it is preferable to shift the position to a side closer to the lens side because the apparatus is miniaturized.

As conditions for generating the overlapping portion T, as shown in FIG. 8, in a case where the beam interval Δ on the irradiation surface and the beam spread σ on the irradiation surface are substantially equal (the intensity obtained by integrating each beam in the region is uniform) and in a case where the beam interval Δ on the irradiation surface>the beam spread σ on the irradiation surface (the intensity obtained by integrating each beam in the region has a distribution), the overlapping portion T is generated. On the other hand, in a case where the beam interval on the irradiation surface Δ>>the beam spread σ on the irradiation surface (for example, in FIG. 7B, the distance between the light emitting unit and the lens=the lens focal length (σ is infinitely 0)), the overlapping portion T does not occur. Therefore, the beam interval Δ and the beam spread σ may be set such that the overlapping portion T is generated. For example, the beam spread σ on the irradiation surface is adjusted by the Far Field Pattern (FFP) of the light source 20 and the beam divergence degree determined by the positional relationship between the focal length of the lens and the light emitting unit. On the other hand, the beam interval Δ on the irradiation surface is adjusted by the element spacing of the light source 20 and the optical system magnification determined by the positional relationship between the focal length of the lens and the light emitting unit. Here, the profile of the beam intensity I of each beam based on the illuminance irradiation surface position (x) is calculated as I=e\hat{ }(−(x−Δ))\hat{ }2/σ\hat{ }2), where Δ: beam interval on the irradiation surface, and σ: beam spread on the irradiation surface.

Further, the irradiation optical system 30 may irradiate the object to be measured 80 with light from the light source 20 such that the light is uniform for each light emitting section, or irradiate the object to be measured 80 with light so as to be point irradiation.

In the light source 20 provided with a plurality of VCSELs as in the present exemplary embodiment, the light emission timing of each VCSEL is deviated due to external factors such as driving conditions and temperature conditions, individual differences, and changes over time. Therefore, in the present exemplary embodiment, the amount of deviation in the measurement distance in the overlapping portion T is determined, and at least one of the light emission of the light source 20 or the light reception of the 3D sensor 5 is corrected such that the difference disappears. For example, the amount of deviation is determined by comparing the measurement distance obtained from the light receiving result of the overlapping portion T in the light receiving section 26₂₁ when the light emitting section 24₂₁ emits light with the measurement distance obtained from the light receiving result of the overlapping portion T in the light receiving section 26₂₁ when the light emitting section 24₂₂ emits light, and the correction value is calculated from the amount of deviation. A correction value for correcting the deviation in the light emission timing of each VCSEL is obtained by similarly determining the deviation amount for each overlapping portion T.

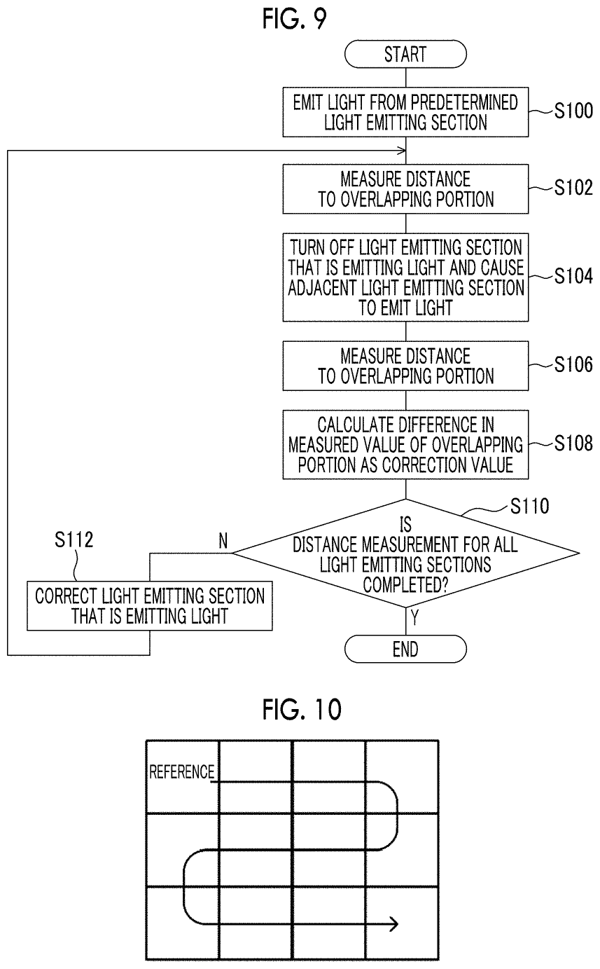

Next, the operation of the measurement apparatus 1 according to the present exemplary embodiment will be described. FIG. 9 is a flowchart showing the flow of a calibration process executed by the control unit 8 of the measurement apparatus 1 according to the present exemplary embodiment. A measurement process shown in FIG. 9 is executed by the CPU 12A reading the calibration program 16A stored in the storage unit 16.

In step S100, the CPU 12A emits light from a predetermined light emitting section 24, and the process proceeds to step S102. That is, the MOS transistor 51 of the drive unit 50 is turned on and the switch element SW is turned on such that the VCSEL of the light emitting section 24 of the light source 20 emits light. This makes the VCSEL of the predetermined light emitting section 24 emit light. As a predetermined light emitting section 24, as an example, the light emitting section 24₁₁ on the upper left of FIG. 4 emits light.

In step S102, the CPU 12A measures the distance to the overlapping portion T and proceeds to step S104. That is, with reference to the section correspondence table 16C, the light receiving amount of the light receiving element PD belonging to the overlapping portion T of the light receiving section 26 corresponding to the light emitting section 24 is acquired from the 3D sensor 5, and the distance to the object to be measured is measured by the above-described phase difference method. For example, in a case where the light emitting section 24₁₁ emits light, the distance is measured based on the light receiving amount of the light receiving elements PDs in the overlapping portion T of the light receiving section 26₁₁ and the light receiving section 26₁₂.

In step S104, the CPU 12A turns off the light emitting section 24 that is emitting light, causes the adjacent light emitting section 24 to emit light, and proceeds to step S106. That is, the MOS transistor 51 of the drive unit 50 is turned on and the switch element SW is turned on such that the VCSEL of the light emitting section 24 adjacent to the predetermined light emitting section 24 of the light source 20 emits light. This makes the VCSEL of the light emitting section 24 adjacent to the predetermined light emitting section 24 emit light.

In step S106, the CPU 12A measures the distance to the overlapping portion T and proceeds to step S108. That is, with reference to the section correspondence table 16C, the light receiving amount of the light receiving element PD belonging to the overlapping portion T of the light receiving section 26 corresponding to the light emitting section 24 is acquired from the 3D sensor 5, and the distance to the object to be measured is measured by the above-described phase difference method. The overlapping portion T is an overlapping portion T corresponding to step S102.

In step S108, the CPU 12A calculates the difference in the measured value of the overlapping portion T as a correction value, and proceeds to step S110. Thus, a correction value for correcting the distance difference generated in the adjacent light emitting sections 24 can be obtained. As the correction value, a correction value for correcting the light emission of the light source 20 may be calculated, a correction value for correcting the light reception of the 3D sensor 5 may be calculated, or a correction value for correcting both may be calculated.

In step S110, the CPU 12A determines whether or not the distance measurement for all the light emitting sections is completed. Ina case where the determination is positive, the process proceeds to step S112, and in a case where the determination is negative, a series of processes is ended.

In step S112, the CPU 12A corrects the light emitting section 24 that is emitting light, returns to step S102, and repeats the above-described process. That is, correction is made by using a correction value that corrects at least one of the light receiving result of the light receiving element PD of the light receiving section 26 corresponding to the light emitting section 24 that is emitting light or the light emitting amount of the VCSEL of the light emitting section 24.

In the process of FIG. 9, for example, as shown in FIG. 10, by performing the above process in order from the light emitting section 24 of the predetermined reference in the direction of the arrow, a correction value according to the reference can be obtained. Further, the reference and the measurement order are not limited to the order shown in FIG. 10, and another position may be used as a reference, or another measurement order may be applied.

### Second Exemplary Embodiment

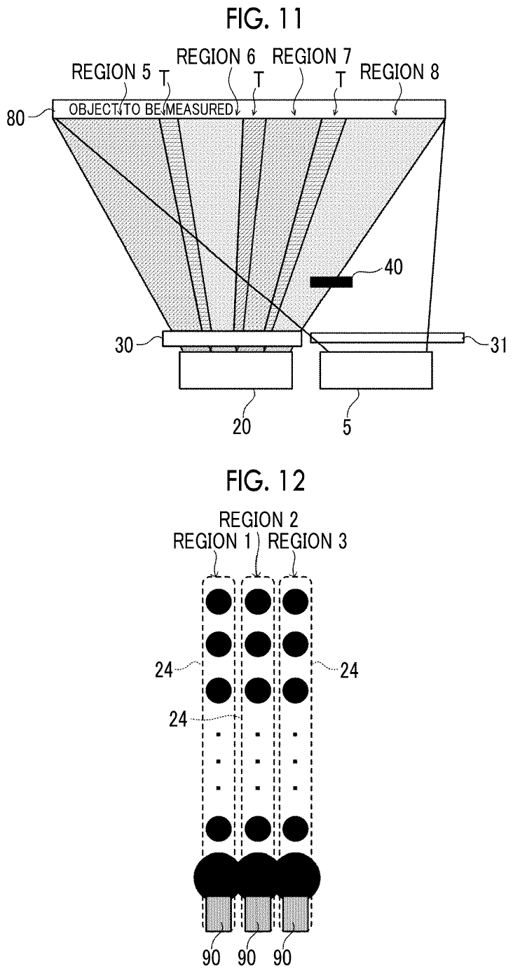

Next, a second exemplary embodiment will be described. The same parts as parts in the first exemplary embodiment are designated by the same reference numerals, and detailed description thereof will be omitted. FIG. 11 is a diagram showing an optical device according to a second exemplary embodiment.

In the first exemplary embodiment, the relative error between the sections disappears, but the deviation from the true value cannot be corrected. Therefore, in the second exemplary embodiment, as shown in FIG. 11, a distance reference unit 40 is provided in the apparatus.

The distance reference unit 40 is provided on the cover glass, for example, by increasing the reflectance of a part of the outermost periphery of the cover glass provided at a position where the distance is known. Alternatively, a member having a high reflectance may be provided on the optical path of the light source 20 separately from the cover glass.

Further, in a case where the distance reference unit 40 is provided on the optical path of one light emitting section 24, the section is a reference, and the same process as in the first exemplary embodiment is performed to calculate a correction value for correcting the deviation from the true value.

### Third Exemplary Embodiment

Next, a third exemplary embodiment will be described. The same parts as parts in the first exemplary embodiment are designated by the same reference numerals, and detailed description thereof will be omitted.

In the above exemplary embodiment, an example in which all VCSELs of the adjacent light emitting sections 24 are overlapped, as the overlapping portion T has been described, all the VCSELs of the adjacent light emitting sections 24 do not need to overlap, and only parts thereof may overlap, with respect to the overlapping portion T.

In the third exemplary embodiment, an example in which the overlapping portion T is generated such that some VCSELs in the adjacent light emitting sections 24 overlap will be described. FIG. 12 is a diagram showing an example in which the overlapping portion T is generated such that such that some VCSELs in the adjacent light emitting sections 24 overlap. The black circles in FIG. 12 indicate the beam profiles of the VCSELs on the irradiation surface.

As shown in FIG. 12, in a case of the light emitting section 24 in which the VCSELs are arranged in one row, light emitted from some VCSELs, like the VCSELs on one end side, may be overlapped, instead of causing all the VCSELs in the adjacent sections to be overlapped. The example of FIG. 12 shows beam profiles on the irradiation surface, and shows an example in which the light emitted from one VCSEL on the gate electrode 90 side is overlapped. The gate electrode 90 corresponds to a coupling portion between the wiring portion that sends a signal to each light emitting section 24 and the light source 20.

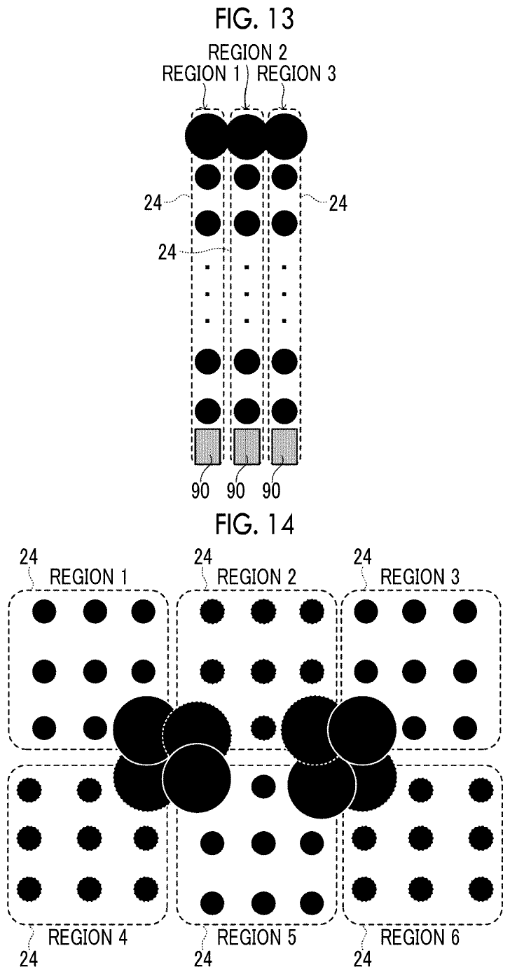

As shown in FIG. 12, in a case where only one VCSEL is overlapped, it is preferable to overlap the light emitted from, for example, the VCSEL far from the gate electrode 90, as shown in FIG. 13, instead of the gate electrode 90 side. That is, the farther from the gate electrode 90, the greater the amount of deviation in the light emission timing than the closer, and in a case of correcting the light emission timing, it is easier to correct the light emission timing with the later timing as a reference. Although FIGS. 12 and 13 show an example in which the light emitted from one VCSEL is overlapped, the light emitted from two or more VCSELs may be overlapped.

Further, in a case where the VCSELs are two-dimensionally arranged in the light emitting section 24 as in the above exemplary embodiment, as shown in FIG. 14, light emitted from the VCSELs in the adjacent portions at the corners of the respective light emitting sections 24 may overlap. In the example of FIG. 14, an example is shown in which the beam profile is adjusted such that light emitted from one VCSEL at the corner of each of the regions 1, 3, 4, and 6 is overlapped, and the beam profile is adjusted such that light emitted from two VCSELs at the corners of each of the regions 2 and 5 is overlapped.

Here, a method of generating the overlapping portion T by overlapping only the light emitted from some VCSELs as in the third exemplary embodiment will be described.

As a first method, there is a method of making the opening from which the light of the VCSEL is emitted different. Specifically, the VCSEL has a layer called a current constriction layer that is made of a material having a high composition ratio of Al, such as AlAs, and has a portion in which the Al becomes Al₂O₃ by oxidation, the electric resistance becomes high, and the current is unlikely to flow. In a case where the current constriction layer is oxidized, the oxidation proceeds from the peripheral portion to the central portion in the circular cross section. By not oxidizing the central portion, the central portion in the cross section of the VCSEL becomes a current passing region where current easily flows, and the peripheral portion becomes a current blocking region where current does not easily flow. Then, the VCSEL emits light in a portion where the current path is restricted by the current passing region of the light emitting layer. The region on the surface of the VCSEL corresponding to this current passing region is a light emitting point and is a light emitting port. Therefore, the beam profile σ on the irradiation surface is changed by expanding the FFP of the light source by making the oxidation diameter, which is the diameter of the current passing region, different from the oxidation diameter of other elements.

As a second method, by providing a microlens corresponding to each VCSEL as the irradiation optical system 30, and making the lens shape of the portion where the beams overlap different from the others, the beam profile σ on the irradiation surface is changed.

### Fourth Exemplary Embodiment

Next, a fourth exemplary embodiment will be described. The same parts as parts in the first exemplary embodiment are designated by the same reference numerals, and detailed description thereof will be omitted.

In each of the above exemplary embodiments, the irradiation optical system 30 shapes the light from the light source 20 such that an overlapping portion T is generated in which adjacent regions irradiated with light from the plurality of light emitting sections 24 overlap on the object to be measured 80 and the 3D sensor 5, but in the present exemplary embodiment, the method of generating the overlapping portion T is different.

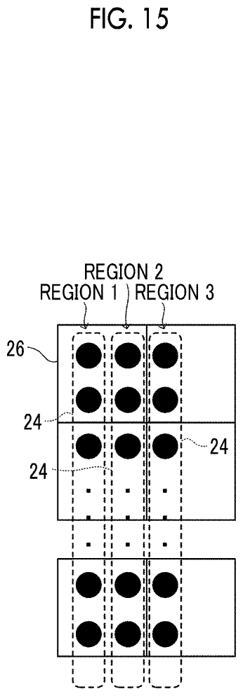

In the present exemplary embodiment, in the overlapping portion T, light does not actually overlap, and the positional relationship between the light source 20 and the 3D sensor 5 is set and light is emitted through the irradiation optical system 30 such that light is exposed on the region of the 3D sensor 5, the region being regarded as one piece of data. For example, as shown in FIG. 15, the light source 20 is set as light emitting sections 24 in which VCSELs are arranged in a row, and the light emitted from the VCSELs of the adjacent light emitting sections 24 is applied to the light receiving section 26 regarded as one piece of data. Thus, the light emitted from the VCSELs of the adjacent light emitting sections 24 is equivalent to overlapping on the 3D sensor, so that the light receiving section 26 is regarded as the overlapping portion T.

As described above, in the present exemplary embodiment, instead of actually causing the light to be overlapped, even in a case where the adjacent light emitting sections 24 are overlapped, the correction value can be obtained by performing the same process as in the above exemplary embodiment.

In this case, in a case where it is found from the output results of the region 1, the region 2, and the region 3 of FIG. 15 that the light emission delay occurs in the region 2, the correction may be made such that a sensor region matches the result of the same region 1.

That is, in a case where there seems to be abnormality in the region 2, in a case where the correction is made such that the regions 3 and the region 2 are the same, the correction includes the light receiving error of the sensor, so that for example, a correction may be made with the overlapping region 1 on the light receiving element PD.

In a case where the sensor region can be made variable, the correction may be made in both the region 1-region 2 and the region 3-region 2.

The control unit 8 specifies a region where an abnormality such as a light emission delay has occurred in region 2, for example, by using a well-known technique such as checking whether it is continuous or not, determining whether or not it is close only by the change over time, determining whether or not it is close even in a case where the position of the camera is moved, and comparing with a 2D camera image. In this case, the control unit 8 functions as an abnormality specifying unit.

Further, also in each of the above-described exemplary embodiments, a region in which an abnormality is likely to occur may be specified and corrected with the region in which there is no abnormality as a reference.

Further, in each of the above exemplary embodiments, in a case where a plurality of light receiving elements PDs are included in the light receiving section 26 corresponding to the overlapping portion T, the correction value may be obtained by calculating the average value of the light receiving results of the plurality of light receiving elements PDs as the distance measurement value in the overlapping portion T. Alternatively, the total value of the light receiving results of the plurality of light receiving elements PD may be calculated to obtain the correction value.

Incidentally, as in the present exemplary embodiment, in a light emitting unit provided with a plurality of light emitting elements, a deviation is generated in the light emission timing of each light emitting element due to external factors such as driving conditions and temperature conditions. Then, due to the deviation in the light emission timing, the reflected light cannot be uniformly received in the light receiving unit that receives the reflected light of the light emitted from each light emitting element to the object to be measured.

Therefore, a purpose may be providing a distance measurement apparatus capable of uniformly receiving the reflected light, as compared with the case where the light emitted from the light emitting unit provided with a plurality of light emitting elements is directly applied to the object to receive the reflected light.

In this case, the distance measurement apparatus may include a light emitting unit that has a plurality of light emitting elements, and is able to be driven independently in a plurality of regions, a light receiving unit provided with a plurality of light receiving elements that receive reflected light of light applied to an object from the light emitting unit, and a shaping unit that causes an overlapping portion to be generated in which light reception of the reflected light overlaps in the adjacent regions, on the light receiving unit.

In the embodiments above, the term “processor” refers to hardware in a broad sense. Examples of the processor include general processors (e.g., CPU: Central Processing Unit) and dedicated processors (e.g., GPU: Graphics Processing Unit, ASIC: Application Specific Integrated Circuit, FPGA: Field Programmable Gate Array, and programmable logic device).

In the embodiments above, the term “processor” is broad enough to encompass one processor or plural processors in collaboration which are located physically apart from each other but may work cooperatively. The order of operations of the processor is not limited to one described in the embodiments above, and may be changed.

Further, the process performed by the control unit 8 of the measurement apparatus 1 according to the above exemplary embodiment may be a process performed by software, a process performed by hardware, or a combination of both. Further, the process performed by the control unit 8 of the measurement apparatus 1 may be stored in a storage medium as a program and distributed.

Further, the present invention is not limited to the above, and it is needless to say that the present invention can be variously modified and implemented within a range not deviating from the gist thereof.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A distance measurement apparatus comprising:
a light emitting unit that has a plurality of light emitting elements, and is able to be driven independently in a plurality of regions;
a light receiving unit provided with a plurality of light receiving elements that receive reflected light of light applied to an object from the light emitting unit;
a shaping unit that causes an overlapping portion to be generated in which light reception of the reflected light overlaps in the adjacent regions, on the light receiving unit;
a measurement unit that measures a distance to the object, from a difference between a waveform of light received by the light receiving unit and a waveform of light emitted by the light emitting unit; and
a correction unit that corrects a distance difference in the reflected light in the adjacent regions, by using a distance measurement value in the overlapping portion measured by the measurement unit.

2. The distance measurement apparatus according to claim 1, wherein
the shaping unit shapes light emitted from the light emitting unit to cause the overlapping portion to be generated in which light reception of the reflected light overlaps in the adjacent regions, on the light receiving unit.

3. The distance measurement apparatus according to claim 2, wherein
the shaping unit includes a lens, and causes the overlapping portion to be generated by shifting a position of a focal length of the lens from a position of the light emitting unit.

4. The distance measurement apparatus according to claim 3, wherein
the lens includes a plurality of lenses, and the overlapping portion is generated by shifting a position of a combined focal length of the plurality of lenses from the position of the light emitting unit.

5. The distance measurement apparatus according to claim 3, wherein
the shaping unit causes the overlapping portion to be generated by shifting the position of the light emitting unit from the position of the focal length toward the lens side.

6. The distance measurement apparatus according to claim 4, wherein
the shaping portion causes the overlapping portion to be generated by shifting the position of the light emitting unit from the position of the focal length toward the lens side.

7. The distance measurement apparatus according to claim 1, wherein
the shaping unit causes the overlapping portion, in which light reception of the reflected light overlaps in the adjacent regions, to be generated in some adjacent regions.

8. The distance measurement apparatus according to claim 7, wherein
the shaping unit causes the overlapping portion, in which light reception of the reflected light overlaps in the adjacent regions, to be generated in some adjacent regions, by light emitted from the light emitting element located at a position away from a coupling portion between a wiring portion that transmits a signal to each region of the light emitting unit and the light emitting unit.

9. The distance measurement apparatus according to claim 1, wherein
the shaping unit causes the overlapping portion to be generated by allowing light emitted from the adjacent regions to be received in the light receiving region of the light receiving unit, the light receiving region being regarded as one piece of data, and
the correction unit corrects the distance difference by matching a distance measurement value in one region received in the light receiving region with a distance measurement value in the other region.

10. The distance measurement apparatus according to claim 1, further comprising:
a distance reference unit that measures a distance reference in the apparatus.

11. The distance measurement apparatus according to claim 2, further comprising:
a distance reference unit that measures a distance reference in the apparatus.

12. The distance measurement apparatus according to claim 3, further comprising:
a distance reference unit that measures a distance reference in the apparatus.

13. The distance measurement apparatus according to claim 4, further comprising:
a distance reference unit that measures a distance reference in the apparatus.

14. The distance measurement apparatus according to claim 5, further comprising:
a distance reference unit that measures a distance reference in the apparatus.

15. The distance measurement apparatus according to claim 6, further comprising:
a distance reference unit that measures a distance reference in the apparatus.

16. The distance measurement apparatus according to claim 10, wherein
the distance reference unit is provided in a partial region of a cover glass.

17. The distance measurement apparatus according to claim 1, wherein
the correction unit corrects at least one of the light emission of the light emitting unit or the light reception of the light receiving unit to correct the distance difference.

18. The distance measurement apparatus according to claim 1, further comprising:
an abnormality specifying unit that specifies a region in which an abnormality is likely to occur, wherein
the correction unit performs correction, with the region where there is no abnormality as a reference.

19. The distance measurement apparatus according to claim 1, wherein
in a case where there are a plurality of light emitting elements corresponding to the overlapping portion, the correction unit calculates an average value as the distance measurement value in the overlapping portion and performs correction.

20. A non-transitory computer readable medium storing a distance measurement program causing a computer to function as the measurement unit and the correction unit of the distance measurement apparatus according to claim 1.
